(19) United States
(12) Patent Application Publication
(10) Pub. No.: US 2006/0111065 A1
(43) Pub. Date: May 25, 2006

(54) Electronic circuit and method of manufacturing the same

(75) Inventor: Yasuhide Kuroda, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/052,785

(22) Filed: Feb. 9, 2005

(30) Foreign Application Priority Data
Nov. 22, 2004 (JP) 2004-337597

(51) Int. Cl. H04B 1/46

(52) U.S. Cl. 455/188.1; 455/272

(57) ABSTRACT

In an electronic circuit capable of eliminating a direct current component while suppressing deterioration of frequency characteristics in a wide frequency band, the electronic circuit includes a first capacitor, which eliminates, when the wide frequency band is divided into a low frequency band and a high frequency band, the direct current component of the low frequency band, and a plurality of second capacitors each disposed to each fine band when the high frequency band is further divided into fine bands to eliminate the direct current components of the fine bands, wherein the first capacitor and the second capacitor are connected in parallel with each other. There is also provided a method of manufacturing the electronic circuit.

### BACKGROUND OF THE INVENTION

1. Field of the Invention

The present invention relates to an electronic circuit having capacitors for eliminating a direct current component and a method of manufacturing the same.

2. Description of the Related Art

Electronic circuits having capacitors are widely utilized in various fields (refer to, for example, Japanese Patent Publication No. 2882994, and the like) and used to eliminate a direct current component in a transmission circuit and a measurement circuit.

Incidentally, in transmission circuits for transmitting signals in a wide frequency band from a low frequency including a microwave zone and a milli-wave zone to a high frequency, the wide frequency band is divided into a low frequency band and a high frequency band to eliminate the direct current component of the wide frequency band. Then, a capacitor having a relatively large electrostatic capacitance may be used as a capacitor for eliminating the direct current component of the low frequency band, and a capacitor having a relatively small electrostatic capacitance may be used as a capacitor for eliminating the direct current component of the high frequency band (refer to, for example, Japanese Patent Application Laid-Open Publication No. 5-235602).

However, in an electronic circuit handling a microwave and a milli-wave, since a direct current component must be eliminated in a wide frequency band from several hundreds of kilohertz to several tens of gigahertz, there is a tendency that reflection characteristics are lowered in a frequency near to a boundary between the divided frequency bands even if the technique disposed in Japanese Patent Application Laid-Open Publication No. 5-235602 is applied. Further, problems are reported in that a transmission loss is greatly increased in a high frequency band of 35 GHz or more and that a loss such as a ripple occurs in a frequency near to 1 GHz.

### SUMMARY OF THE INVENTION

The present invention has been made in view of the above circumstances and provides an electronic circuit that can eliminate a direct current component while suppressing deterioration of frequency characteristics in a wide frequency band and a method of manufacturing the same.

An electronic circuit of the present invention for solving the above problems includes a first capacitor, which eliminates, when a frequency band is divided into a low frequency band and a high frequency band, the direct current component of the low frequency band, and second capacitors each disposed to each fine band when the high frequency band is further divided into fine bands to eliminate the direct current components of the fine bands, wherein the first capacitor and the second capacitor are connected in parallel with each other.

In the technique explained in the description of related art, which eliminates the direct current component by dividing the frequency band into the two frequency bands, it is contemplated that elimination of the direct current component of a wider frequency band increases the frequency band to be born by each capacitor, thereby frequency characteristics are deteriorated. According to the electronic circuit of the present invention, the frequency band born by each capacitor is narrowed by further dividing the high frequency band into the fine bands. As a result, capacitors optimum to respective frequency bands can be used, thereby the direct current component can be eliminated in a wide frequency band while suppressing deterioration of the frequency characteristics.

In the electronic circuit of the present invention, the electrostatic capacitance of the first capacitor may be larger than the electrostatic capacitances of the second capacitors, and the electrostatic capacitances of the second capacitors may be different from each other.

Since a capacitor having a large electrostatic capacitance has higher impedance in a higher frequency, sufficient frequency characteristics cannot be obtained. In contrast, since a capacitor having a small electrostatic capacitance has higher impedance in a lower frequency, sufficient frequency characteristics cannot be obtained. Accordingly, in the above arrangement, the first capacitor and the second capacitors can be provided with electrostatic capacitances optimum to the respective frequency bands.

It is preferable that the electronic circuit of the present invention include a first conductive pattern extending in a strip shape, and a second conductive pattern extending in a strip shape at a predetermined interval from the extreme end of the first conductive pattern, wherein one electrodes of the first capacitor and the second capacitors may be connected to the first conductive pattern, and that the electronic circuit further include a conductive lead plate to which the other electrode of the first capacitor is connected as well as the other electrodes of the second capacitors are commonly connected and which is connected to the second conductive pattern.

As described above, since not only the electrodes of the second capacitors are connected commonly but also the electrode of the first capacitor are also connected commonly in addition to the electrodes of the second capacitors, no additional connection member is necessary to connect the other electrode of the first capacitor to the second conductive pattern, thereby the size of the electronic circuit can be reduced. Further, the second capacitors can be integrated with each other by the lead plate, which permits the electronic circuit to be manufactured easily.

In the electronic circuit of the present invention, it is more preferable that the connecting position of the lead plate at which the electrode of the capacitor, which eliminates the direct current component of the highest frequency fine band, of the capacitors is connected be located nearer to the second conductive pattern than the connecting position of the lead plate at which the electrode of the other capacitor is connected.

With the above arrangement, the connection length, which connects the first conductive pattern to the second conductive pattern, of the capacitor which eliminates the direct current component of the highest frequency fine band, can be reduced, thereby deterioration of the frequency characteristics can be suppressed.

Note that it is more preferable that a capacitor, which eliminates the direct current component of a higher frequency band, have a shorter connection length to the second conductive pattern.

It is also preferable that the electronic circuit of the present invention include a first conductive pattern extending in a strip shape, and a second conductive pattern extending in a strip shape at a predetermined interval from the extreme end of the first conductive pattern, wherein the first capacitor may be disposed such that the electrode on one end side thereof is connected to the first conductive pattern and the electrode on the other end side thereof is disposed in an attitude in which the electrode is raised from the extreme end of the first conductive pattern, and that the electronic circuit further include a lead plate which connects the electrode on the other end side of the first capacitor to the second conductive pattern, wherein any of the second capacitors is sandwiched between the lead plate and the first conductive pattern in a direction where the pairs of electrodes of the second capacitors face.

According to the above arrangement, the capacitors can be laminated in the thickness direction (vertical direction) of the substrate when they are disposed, thereby a much smaller electronic circuit can be realized.

A method of manufacturing an electronic circuit of the present invention includes: a preparation step of preparing a low frequency capacitor, which eliminates the direct current component of a low frequency band, when a frequency band is divided into the low frequency band and a high frequency band, a first chip capacitor, which eliminates the direct current component of a lower frequency fine band, and a second chip capacitor which eliminates the direct current component of a higher frequency fine band, when the high frequency band is further divided into the lower frequency fine band and the higher frequency fine band;

a V-shape bending step of pressing the extreme end of a conductive lead plate extending horizontally against a V-shaped groove while keeping the rear end thereof horizontally to thereby form the side surface of the extreme end in a V-shape having a V-shaped apex so that there is formed a space, which is sandwiched between an extreme end side inclining portion that inclines from the extreme end to the V-shaped apex and a horizontal side inclining portion that inclines from the horizontal portion of the lead plate to the V-shaped apex;

a lead integration step of obtaining a lead integration member in which one electrode of the first chip capacitor is connected to the surface of the extreme end side inclining portion on the space side thereof as well as one electrode of the second chip capacitor is connected to the surface of the horizontal side including portion on the space side thereof, and a conductor is interposed between the other electrode of the first chip capacitor and the other electrode of the second chip capacitor;

a bridge step of disposing the lead integration member with the V-shaped apex facing upward so that the conductor is located on a first conductive pattern of a substrate having the first conductive pattern and a second conductive pattern disposed on the front surface thereof, the first conductive pattern extending in a strip shape, and the second conductive pattern extending in a strip shape at a predetermined interval from the extreme end of the first conductive pattern as well as the rear end of the lead plate is positioned on the second conductive pattern, and connecting the conductor to the first conductive pattern as well as connecting the rear end of the lead plate to the second conductive pattern; and

a low frequency capacitor connection step of disposing the low frequency capacitor so that the pair of electrodes thereof are disposed toward the first conductive pattern along the inclination of the extreme end side inclining portion, and connecting one electrode of the low frequency capacitor to the surface of the extreme end side inclining portion opposite to the surface thereof on the space side as well as connecting the other electrode of the low frequency capacitor to the first conductive pattern.

According to the method of manufacturing the electronic circuit of the present invention, the low frequency capacitor, the first chip capacitor, and the second chip capacitor are connected in parallel with each other. Further, since the first and second chip capacitors are used to eliminate the direct current component of the high frequency band, the frequency band born by each capacitor is narrowed, thereby capacitors optimum to the respective frequency bands can be used. As a result, the electronic circuit which can eliminate the direct current component while suppressing deterioration of the frequency characteristics in the wide band can be manufactured by the method of manufacturing the electronic circuit of the present invention. Although the three capacitors are mounted in the electronic circuit of the present invention, the first and second chip capacitors are integrated by the lead integration process, thereby the number of components to be mounted is reduced as well as they can be easily mounted on the substrate. The first and second chip capacitors are disposed in the attitude in which they are inclined in the thickness direction of the substrate. Accordingly, the surface area of the substrate occupied by these capacitors can be reduced as compared with the case in which these capacitors are disposed horizontally along the surface of the substrate. Further, the one electrode of the low frequency capacitor is disposed on the first chip capacitor and moreover the low frequency capacitor is also disposed in the attitude in which it is inclined in the thickness direction of the substrate. Accordingly, the surface area of the substrate occupied by the low frequency capacitor can be reduced as compared with the case in which the low frequency capacitor is disposed horizontally along the surface of the substrate. As a result, the surface of the substrate can be saved in the electronic circuit manufactured by the method of manufacturing the electronic circuit of the present invention.

In the above method, the preparation step may include preparing a chip capacitor having an electrostatic capacitance smaller than that of the first chip capacitor as the second chip capacitor as well as preparing a capacitor having an electrostatic capacitance larger than that of the first chip capacitor as the low frequency capacitor.

In the method of manufacturing the electronic circuit of the present invention, it is preferable that the bridge step include disposing the lead integration member so that the conductor is in contact with the first conductive pattern as well as the rear end of the lead plate be in contact with the second conductive pattern and securing the rear end of the lead plate to the second conductive pattern after the conductor is secured to the first conductive pattern.

When the rear end of the lead plate is located at a position raised from the second conductive pattern, the rear end of the raised lead plate must be pressed downward when the rear end of the second conductive pattern is secured to the second conductive pattern after the conductor is secured to the first conductive pattern. When it is intended to press the rear end of the lead plate downward in the state that the conductor is secured to the first conductive pattern, there is a possibility that a part of the first conductive pattern secured to the conductor is exfoliated because the conductor is pulled upward. In the above arrangement, the lowermost portion of the conductor and the rear end of the lead plate are located on the same horizontal surface. Accordingly, it is not necessary to press the rear end of the lead plate downward in the state that the conductor is secured to the first conductive pattern, and thus there is not the possibility that a part of the first conductive pattern is exfoliated.

According to the present invention, there can be provided the electronic circuit and the method of manufacturing the electronic circuit, wherein the electronic circuit can eliminate the direct current component while suppressing deterioration of the frequency characteristics in the wide band.

### BRIEF DESCRIPTION OF THE DRAWINGS

FIG. 1 is a view showing how a lead plate is set on a heater stage;

FIG. 2 is a view showing how a V-shape bending process is executed;

FIG. 3 is a view showing the lead plate when a compression tool is moved upward from a V-shaped groove;

FIG. 4 is a view showing how a lead integration process is executed;

FIG. 5 is a view showing a lead integrated member disposed on a substrate;

FIG. 6 is a view showing how the rear end of the lead plate is secured to a second conductive pattern;

FIG. 7 is a view showing how a low frequency capacitor connection process is executed;

FIG. 8 is a schematic view of an electronic circuit manufactured by a method of manufacturing the electronic circuit of an embodiment when it is viewed laterally;

FIG. 9 is a schematic view of the electronic circuit shown in FIG. 8 when it is viewed vertically downward;

FIG. 10 is a circuit diagram of the electronic circuit shown in FIG. 8;

FIG. 11 is a view showing how the electronic circuit shown in FIG. 8 is mounted on a metal cabinet;

FIG. 12 is a view showing how the electronic circuit mounted on the metal cabinet is connected to other substrate;

FIG. 13 is a graph showing the frequency characteristics of the electronic circuit shown in FIG. 8;

FIG. 14 is a view showing a modification in which a chip capacitor is disposed horizontally;

FIG. 15 is a view showing a modification in which a seat is used in place of an AuSn ball shown in FIG. 4;

FIG. 16 is a view showing a modification provided with a GSG (ground-signal-ground) micro-strip line;

FIG. 17 is a view showing a modification in which the horizontal portion of a lead plate of a lead integrated member is slightly inclined; and

FIG. 18 is a view showing a state in which the lead integrated member having a copper ball shown in FIG. 17 is disposed with its V-shaped apex facing upward.

### DETAILED DESCRIPTION OF THE INVENTION

Embodiments of the present invention will be explained below with reference to the drawings.

First, an embodiment of a method of manufacturing an electronic circuit of the present invention will be explained.

The method of manufacturing the electronic circuit of the embodiment manufactures the electronic circuit to be assembled in a transmission circuit, and the like to eliminate the direct current component of a wide frequency band up to 50 GHz. The electronic circuit manufactured here has three capacitors each of which bears a role of eliminating the direct current component of a predetermined frequency band. That is, the wide frequency band from 0 Hz or more to 50 GHz or less is divided into a low frequency band from 0 Hz or more to less than 15 GHz and a high frequency band from 15 GHz or more to 50 GHz or less. Next, the high frequency band is further divided into two fine bands on the opposite sides of a boundary of 30 GHz. In the following description, a lower frequency fine band of the two fine bands into which the high frequency band is divided is called a low fine band, and a higher frequency fine band of them is called a high fine band. The frequency of the low fine band is from 15 GHz or more to less than 30 GHz, and the frequency of the high fine band is 30 GHz or more to 50 GHz or less.

Since a capacitor having a large electrostatic capacitance has a higher impedance in a higher frequency, it cannot obtain sufficient frequency characteristics, whereas since a capacitor having a small electrostatic capacitance has a higher impedance in a lower frequency, it cannot obtain sufficient frequency characteristics. To cope with this problem, in the method of manufacturing the electronic circuit of the embodiment, first, there is prepared a ceramic capacitor of about 0.1 μF to 0.2 μF having a length of 1 mm, a width of 0.5 mm, and height of 0.5 mm to eliminate the direct current component of the low frequency band of 0 Hz or more to less than 15 GHz. The ceramic capacitor has a pair of electrodes disposed in a lengthwise direction. Further, there is prepared a micro chip capacitor (hereinafter, called a first chip capacitor) of about 100 pF to 200 pF having a length of 0.38 mm, a width of 0.38 mm, and height of 0.2 mm to eliminate the direct current component of the low fine band of 15 GHz or more to less than 30 GHz. Further, there is prepared a micro chip capacitor (hereinafter, called a second chip capacitor) of about 30 pF to 80 pF having a length of 0.38 mm, a width of 0.38 mm, and height of 0.2 mm to eliminate the direct current component of the high fine band of 30 GHz or more to 50 GHz or less. These micro chip capacitors each have a pair of electrodes disposed in a height direction. However, it is known that frequency characteristics are deteriorated in the high frequency band from 30 GHz to 50 GHz unless they are connected in an extremely short distance in conformity with their height because they have a large tolerance in height.

Next, a V-shaped bending process is executed by setting a horizontally extending conductive lead plate on a heater stage on which a V-shaped groove is formed.

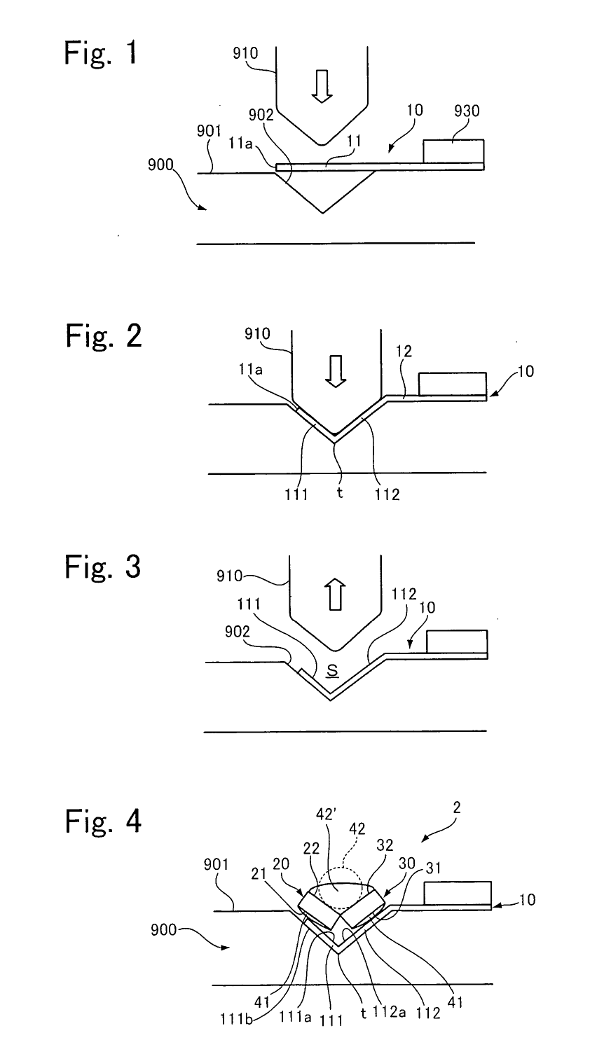

FIG. 1 is a view showing how the lead plate is set on the heater stage, and FIG. 2 is a view showing how the V-shape bending process is executed.

The heater stage 900 shown in FIGS. 1 and 2 is provided with a heating mechanism, and a surface 901 of the heater stage 900 is heated thereby. Further, a compression tool 910 is disposed above the heater stage 900, the compression tool 910 having an extreme end shape that is in coincidence with the V-shaped groove 902 formed on the heater stage 900. The compression tool 910 is free to move upward and downward.

As shown in FIG. 1, the rear end of the horizontally extending conductive lead plate 10 is pressed with a block-shaped presser member 930, and the lead plate 10 is set on the surface 901 of the heater stage 900 such that an extreme end portion 11 of the lead plate 10 is located on the V-shaped groove 902. In this state, since the extreme end portion 11 of the lead plate 10 does not completely traverse the V-shaped groove 902, an extreme end 11a of the lead plate 10 does not come into contact with the surface 901 of the heater stage 900.

Next, the compression tool 910 is moved downward toward the V-shaped groove 902 to thereby press the extreme end portion 11 of the lead plate 10 against the V-shaped groove 902 while keeping the rear end of the lead plate 10 horizontal. With this operation, the side surface of the extreme end portion 11 of the lead plate 10 is formed in a V-shape, and an extreme end side inclining portion 111, which inclines from the extreme end 11a to a V-shaped apex t, and a horizontal side inclining portion 112, which inclines from a horizontal portion 12 to the V-shaped apex t is formed to the extreme end portion 11 of the lead plate 10 as shown in FIG. 2.

FIG. 3 is a view showing the lead plate when the compression tool is moved upward from the V-shaped groove.

When the compression tool 910 is moved upward from the V-shaped groove 902 as shown in FIG. 3, a space S, which is sandwiched between the extreme end side inclining portion 111 and the horizontal side inclining portion 112, is formed to the extreme end side of the lead plate 10.

Subsequently, a lead integration process is executed.

FIG. 4 is a view showing how the lead integration process is executed.

Conductive high temperature joint members 41, which are melted by being heated and solidified by being cooled, are attached to one electrodes 21 and 31 of the first and second chip capacitors 20 and 30 prepared in the preparation process. The electrode 21, to which the high temperature joint member 41 is attached, of the first chip capacitor 20 is disposed on the surface 111a of the extreme end side inclining portion 111 of the lead plate 10 on the space S side thereof, and the electrode 31, to which the high temperature joint member 41 is attached, of the second chip capacitor 30 is disposed on the surface 112a of the horizontal side inclining portion 112 on the space S side thereof. Next, a gold tin (AuSn) ball 42 is interposed between the other electrodes of the first and second chip capacitors 20 and 30, that is, between the electrodes 22 and 32, to which no high temperature joint member 41 is attached. The AuSn ball 42 is a spherical conductor and shown by a dotted line in FIG. 4. The high temperature joint members 41 attached to the respective electrodes 21 and 31 and the AuSn ball 42 are melted by the heat of the surface 901 of the heater stage 900. FIG. 4 shows how the AuSn ball 42 is melted and extends over the entire space S with its spherical shape lost by a solid line. Hereinafter, the AuSn ball 42 extending over the entire space S is called a conductor 42′. When the length and the width of the lead plate 10 are large, unnecessary portions are cut off. It is preferable to make the lead plate 10 as short as possible to reduce its connecting length. Thereafter, the high temperature joint members 41 and the conductor 42′ are cooled by spraying a nitrogen gas to the lead plate 10 on the heater stage 900. After the high temperature joint members 41 and the conductor 42′ are solidified, the lead plate 10 is taken out from the heater stage 900. A lead integrated member 2, in which the first and second chip capacitors 20 and 30 are integrated with the lead plate 10, can be obtained by executing the lead integration process.

Next, abridge process is executed. In the bridge process, first, the lead integrated member 2 is disposed on a glass substrate 50 with the V-shaped apex t directed upward.

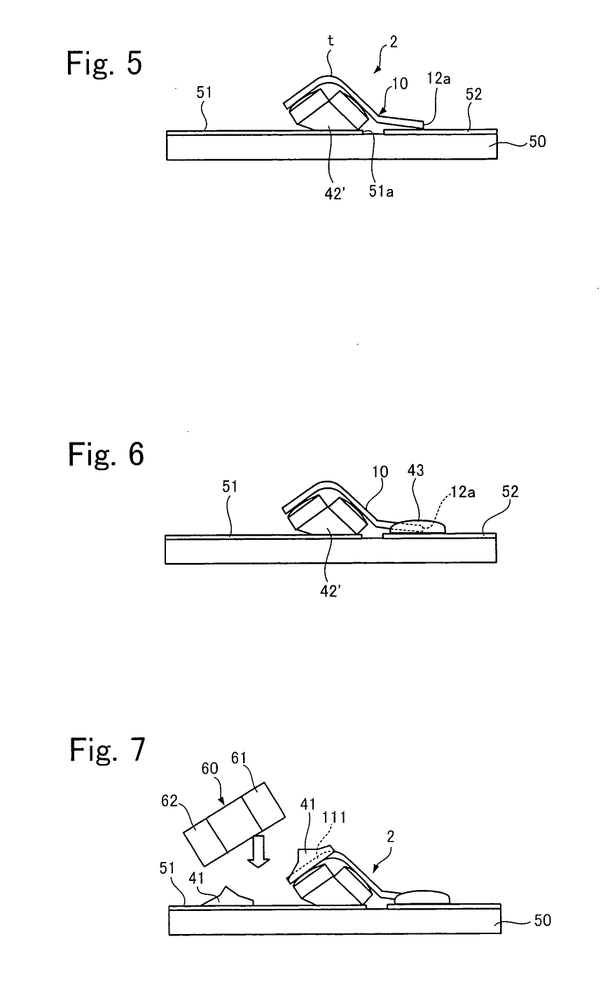

FIG. 5 is a view showing the lead integrated member disposed on the glass substrate 50.

A first conductive pattern 51, which extends in a strip shape, and a second conductive pattern 52, which extends in a strip shape at a predetermined interval from the extreme end 51a of the first conductive pattern 51, are disposed on the surface of the glass substrate 50. In the lead integrated member 2, the conductor 42′ is located on the first conductive pattern 51 as well as the rear end 12a of the lead plate 10 is located on the second conductive pattern 52. In the lead integrated member 2 disposed on the glass substrate 50 shown in FIG. 5, the conductor 42′ is in contact with the first conductive pattern 51 as well as the rear end 12a of the lead plate 10 is in contact with the second conductive pattern 52. First, the conductor 42′ of the lead integrated member 2 disposed on the glass substrate 50 is melted again and secured to the first conductive pattern 51. Thereafter, the rear end 12a of the lead plate 10 is secured to the second conductive pattern 52.

FIG. 6 is a view showing how the rear end of the lead plate is secured to the second conductive pattern.

A conductive adhesive 43 is applied to the portion where the rear end 12a of the lead plate 10 is in contact with the second conductive pattern 52 to thereby secure the rear end 12a of the lead plate 10 to the second conductive pattern 52.

Since the rear end 12a of the lead plate 10 is in contact with the second conductive pattern 52 in FIG. 6, the rear end 12a need not be pressed downward. Since the lead plate 10 is cut off as short as possible to reduce its connecting length, the rear end 12a of the lead plate 10 is liable to float from the second conductive pattern 52. When it is intended to connect the floating rear end 12a to the second conductive pattern 52 by applying the conductive adhesive 43 in a somewhat large amount, the connecting length of the lead plate 10 increases, thereby frequency characteristics are adversely affected. Accordingly, when the rear end 12a of the lead plate 10 floats from the second conductive pattern 52, the rear end 12a must be pressed downward. Even if it is intended to press the rear end 12a downward, it is unlike to be bent because its length is short, thereby productivity is lowered. Further, when it is intended to press the rear end 12a of the lead plate 10 downward in the state that the conductor 42′ is secured to the first conductive pattern 51, the conductor 42′ is pulled upward, and there is a possibility that the first conductive pattern 51 having been secured is partly exfoliated. However, in the lead integrated member 2 shown in FIG. 6, since the lowermost portion of the conductor 42′ is located on the same horizontal surface as that of the rear end 12a of the lead plate 10, the rear end 12a of the lead plate 10 need not be pressed downward in the state that the conductor 42′ is secured to the first conductive pattern 51. Thus, there is not a possibility that the first conductive pattern 51 is partly exfoliated.

Next, a low frequency capacitor connecting process will be executed.

FIG. 7 is a view showing how the low frequency capacitor connection process is executed.

In the low frequency capacitor connection process, first, high temperature joint members 41 are applied to both the extreme end side inclining portion 111 of the lead integrated member 2 secured to the glass substrate 50 and the first conductive pattern 51. Next, the ceramic capacitor 60 prepared in the preparation process is disposed such that the pair of electrodes 61 and 62 are disposed along the inclination of the extreme end side inclining portion 111 toward the first conductive pattern 51 (refer to an arrow in the figure) and exposed to a temperature of 200° C. That is, one electrode 61 of the ceramic capacitor 60 is connected to the surface 111b of the extreme end side inclining portion 111 of the lead integrated member 2 opposite to the surface 111a on the space S side thereof as well as the other electrode 62 of the ceramic capacitor 60 is connected to the first conductive pattern 51.

The method of manufacturing the electronic circuit of the embodiment is as explained above. Subsequently, an electronic circuit manufactured by the method of manufacturing the electronic circuit of the embodiment will be explained.

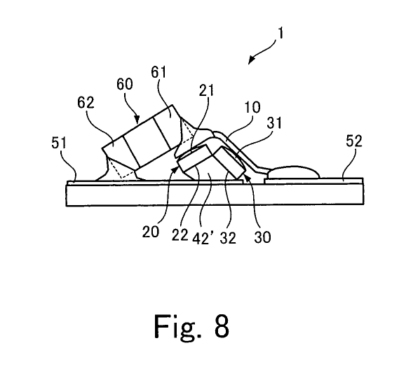

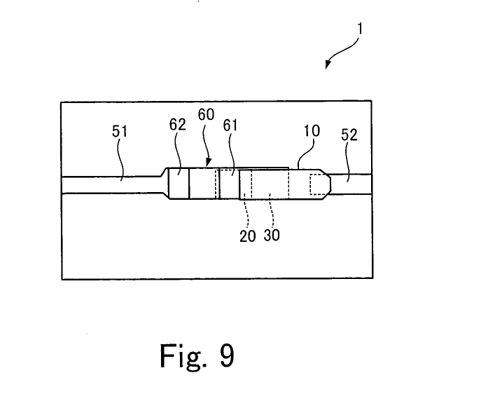

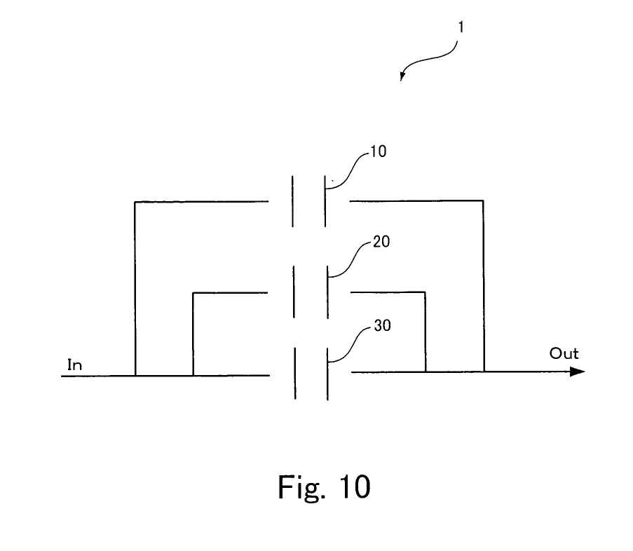

FIG. 8 is a schematic view of the electronic circuit 1 manufactured by the method of manufacturing the electronic circuit of the embodiment when it is viewed laterally, and FIG. 9 is a schematic view of the electronic circuit 1 when it is viewed vertically downward. Further, FIG. 10 is a circuit diagram of the electronic circuit 1 shown in FIG. 8.

The electronic circuit 1 shown in FIG. 8 corresponds also to an embodiment of the electronic circuit of the present invention. The electronic circuit 1 includes a ceramic capacitor 60, which eliminates the direct current component of the low frequency band of 0 Hz or more to less than 15 GHz, a first chip capacitor 20, which eliminates the direct current component of the low fine band of 15 GHz or more to less than 30 GHz, and a second chip capacitor 30, which eliminates the direct current component of the high fine band of 30 GHz or more to 50 GHz or less. As shown in FIG. 10, these capacitors 60, 20, and 30 are connected in parallel with each other. In the electronic circuit 1, one electrode 62 of the ceramic capacitor 60 is connected to a first conductive pattern 51, and one electrodes 22 and 32 of the first and second chip capacitors 20 and 30 are also connected to the first conductive pattern 51 through a conductor 42′.

Further, the electronic circuit 1 shown in FIG. 8 has a conductive lead plate 10. The other electrodes 21 and 31 of the first and second chip capacitors 20 and 30 are commonly connected to the lead plate 10 as well as the other electrode 61 of the ceramic capacitor 60 is also connected to the lead plate 10, in addition to the other electrodes 21 and 31. Accordingly, no additional connection member is necessary to connect the electrode 61 of the ceramic capacitor 60 to a second conductive pattern 52, thereby the electronic circuit 1 can be reduced in size. Further, in the first and second chip capacitors 20 and 30 for eliminating the direct current component of the high frequency band of 15 GHz or more to 50 GHz or less, the second chip capacitor 30, which eliminates the direct current component of the fine band having a higher frequency is connected to the lead plate 10 at a position nearer to the second conductive pattern 52 than the other first chip capacitor 20. That is, the connecting length of the second chip capacitor 30 for connecting the first conductive pattern 51 to the second conductive pattern 52 is shorter than that of the first chip capacitor 20, thereby deterioration of frequency characteristics can be suppressed. Further, the portion of the lead plate 10 where it is connected from the second chip capacitor 30 to the second conductive pattern 52 is formed in a slope shape so that the connecting length of the second chip capacitor 30 is made as short as possible as well as stress can be absorbed thereby. The lead plate 10 is formed in a ridge shape in its entirety so that the first chip capacitor 20 and the ceramic capacitor 60 can be preferably connected in conformity with the slope shape.

Further, in the electronic circuit 1 shown in FIG. 8, the first and second chip capacitors 20 and 30 are disposed in an attitude inclining in the thickness direction of the glass substrate 50, respectively. Accordingly, the area of the surface of the glass substrate 50 occupied by the first and second chip capacitors 20 and 30 is smaller than the area thereof when they are disposed horizontally along the surface of the glass substrate 50. Further, the other electrode 61 of the ceramic capacitor 60 is disposed on the first chip capacitor 20, and moreover the ceramic capacitor 60 is also disposed in an attitude inclining in the thickness direction of the glass substrate 50. Accordingly, the area of the surface of the glass substrate 50 occupied by the ceramic capacitor 60 is smaller than the area thereof when the ceramic capacitor 60 is disposed horizontally along the surface of the glass substrate 50. Further, as shown in FIG. 9, the three capacitors 60, 20, and 30 are disposed without greatly protruding in the width direction of the first and second conductive pattern 51 and 52. Therefore, a mounting space can be saved by the electronic circuit 1 of the present invention.

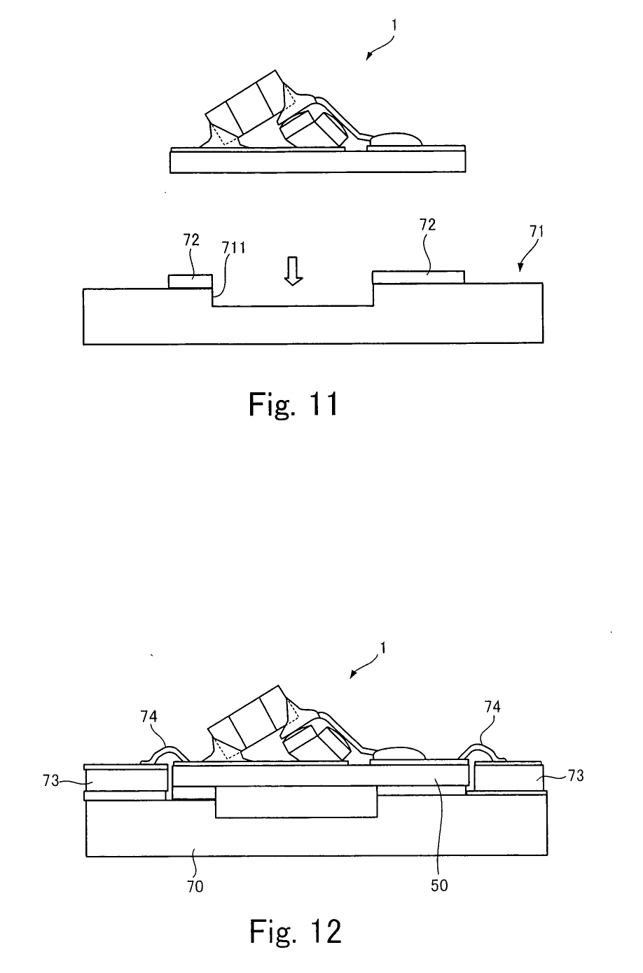

FIG. 11 is a view showing how the electronic circuit 1 shown in FIG. 8 is mounted on a metal cabinet 71.

The electronic circuit 1 shown in FIG. 8 is mounted on the metal cabinet 71. The metal cabinet 71 shown in FIG. 11 is provided with a counter-sunk portion 711 to match impedance, and the electronic circuit 1 shown in FIG. 8 is attached to the counter-sunk portion 711. To attach the electronic circuit 1, a silicone resin 72 is applied to the peripheral edge of the counter-sunk portion 711, and the electronic circuit 1 is bonded to the counter-sunk portion 711 in a less stressed state in an atmosphere of 150° C. When conduction from a front side to a rear side is necessary, a conductive silicone resin is employed as the silicone resin 72, and when it is not necessary, an insulating silicone resin is employed.

FIG. 12 is a view showing how the electronic circuit attached to the metal cabinet is connected to other substrate.

As shown in FIG. 12, interface substrates 73, and the like are disposed adjacent to the electronic circuit 1 attached to the metal cabinet 71 and connected to the electronic circuit 1 through wire bonds 74 or ribbons as required, and the electronic circuit shown in FIG. 8 is assembled as a part of a transmission device.

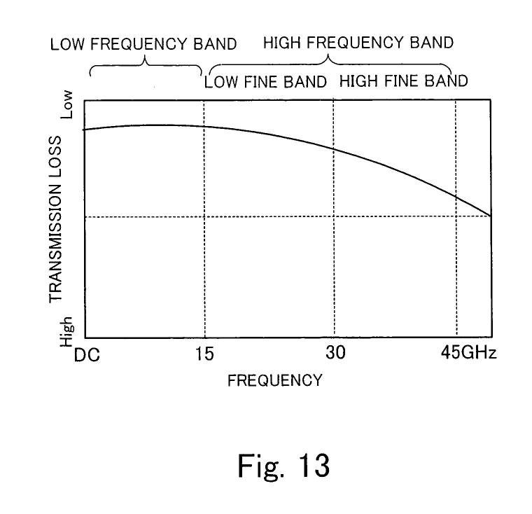

FIG. 13 is a graph showing the frequency characteristics of the electronic circuit shown in FIG. 8.

In the graph show in FIG. 13, a lateral axis shows a frequency, and a vertical axis shows a degree of transmission loss. In the electronic circuit 1 shown in FIG. 8, since transmission loss is considerably suppressed in a wide band from 0 Hz (DC) to 50 GHz, there are solved conventional problems in that a transmission loss is greatly increased in a high frequency band of 35 GHz or more and that a loss such as a ripple occurs in a frequency near to 1 GHz. This is because since the two capacitors, that is, the first and second chip capacitors 20 and 30 are used to eliminate the direct current components of the high frequency band, a most suitable capacitor can be used in each frequency band so that the frequency band born by each capacitor is narrowed. Accordingly, the electronic circuit 1 shown in FIG. 8 can eliminate the direct current component while suppressing deterioration of the frequency characteristics in the wide frequency band.

Subsequently, modifications of the electronic circuit shown in FIG. 8 will be explained below. In the following description, the same components as those described up to now are denoted by the same reference numerals.

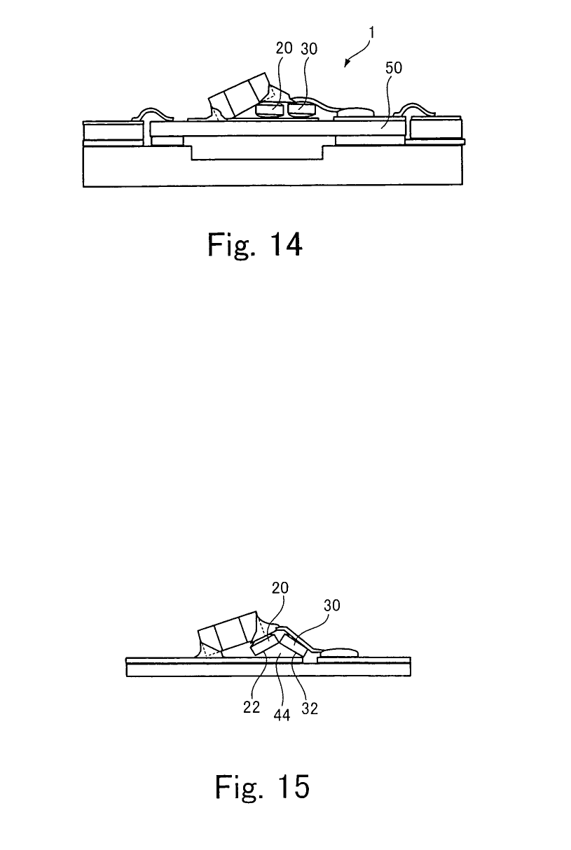

FIG. 14 is a view showing a modification in which first and second chip capacitors 20 and 30 are disposed horizontally.

In the electronic circuit 1 shown in FIG. 8, the first and second chip capacitors 20 and 30 are disposed in the attitude inclining in the thickness direction of the glass substrate 50, respectively. However, when a mounting space has room and the frequency characteristics have a margin, the first and second chip capacitors 20 and 30 may be disposed horizontally along the surface of the glass substrate 50.

FIG. 15 is a view showing a modification using a seat 44 in place of the AuSn ball shown in FIG. 4.

The AuSn ball 42 is interposed between the electrodes 22 and 32 of the first and second chip capacitors 20 and 30 shown in FIG. 4, and the space S is entirely filled with the conductor by melting the AuSn ball 42. However, the conductive triangular prism seat 44 may be disposed laterally in place of the spherical AuSn ball 42. The seat 44 may be formed of a high temperature joint member or may be composed of a metal block. When the seat 44 is formed of the high temperature joint member, even if the space S is not completely filled therewith, since the seat 44 is melted by the heat of the surface 901 of the heater state, the seat 44 spreads over the entire space S, thereby the space S is filled with the conductor. In contrast, when the seat 44 composed of the metal block is used, the seat 44 must be formed in such a shape that the space S can be completely filled with the metal block from the beginning.

Further, the space S may be filled in such a manner that a high temperature joint member composed of AuSn are applied to each of the electrodes 22 and 32 of the first and second chip capacitors 20 and 30, and an AuGe ball, an AuSi ball or an Au plated copper alloy ball, for example, which has a melting point higher than the high temperature joint member is used in place of the AuSn ball 42. In this case, the high temperature joint members applied to the electrodes 22 and 32 are integrated with the ball by melting the high temperature joint member by the heat of the surface 901 of the heater stage.

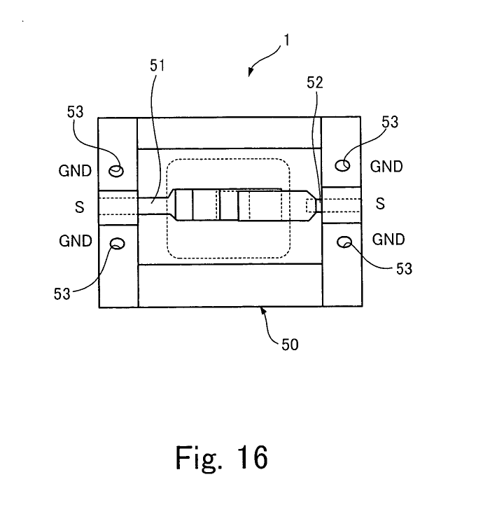

FIG. 16 is a view showing a modification provided with a GSG (ground-signal-ground) micro-strip line.

As shown in FIG. 16, the electronic circuit 1 may be provided with a GSG micro-strip line structure by using the first and second conductive patterns 51 and 52 as signal lines S as well as forming a ground line GND provided with a small diameter via 53 on a glass substrate 50.

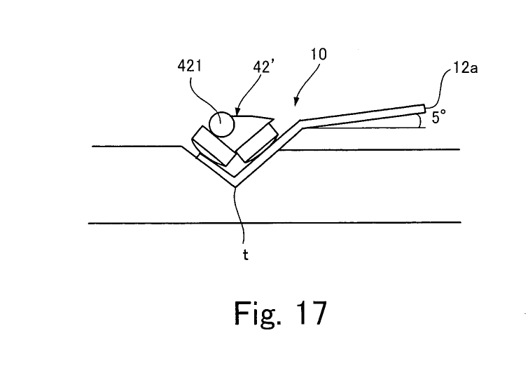

FIG. 17 is a view showing a modification in which the horizontal portion of a lead plate 10 of a lead integration member is slightly inclined.

As described above, when the rear end 12a of the lead plate 10 is located at a position raised from the second conductive pattern 52, there is a possibility that a part of the first conductive pattern 51 is exfoliated. To permit the lowermost portion of the conductor 42′ to be located on the same horizontal surface as that of the rear end 12a of the lead plate 10, the rear end 12a of the lead plate 10 is inclined about 5° in a direction opposite to the direction where the V-shaped apex faces (upward direction in FIG. 17) as shown in FIG. 17 before the unnecessary portion of the lead plate 10 is cut off in the lead integration process. When the unnecessary portion of the lead plate 10 is cut off, the rear end of the lead plate 10 is cut off so that the lowermost portion of the conductor 42′ is located on the same horizontal surface as that of the rear end 12a of the lead plate 10. Further, FIG. 17 shows that the uppermost portion of the conductor 42′ is formed of a Ni—Au plated copper ball 421.

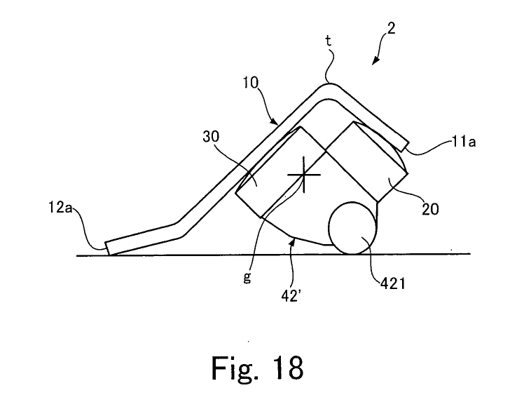

FIG. 18 is a view showing the state in which the lead integration member having the copper ball shown in FIG. 17 is disposed with its V-shaped apex facing upward.

When the lead integrated member 2 is disposed with the V-shaped apex t facing upward in the bridge process, the copper ball 421 is set to the lowermost portion of the conductor 42′. The copper ball 421 is disposed nearer to the first chip capacitor 20 of the first and second chip capacitors 20 and 30. That is, since the copper ball 421 is disposed nearer to the extreme end 11a of the lead plate 10, the center of gravity g of the lead integration member is located nearer to the rear end 12a of the lead plate 10 than the copper ball 421, i.e. the lowermost portion of the conductor 42′. Since the center of gravity g of the lead integrated member 2 is located nearer to the rear end 12a of the lead plate 10 as described above, the rear end 12a can be securely prevented from being raised from the second conductive pattern 52 in the state that the conductor 42′ is secured to the first conductive pattern 51.

In the description up to now, the two capacitors are used to eliminate the direct current components of the high frequency band of 15 GHz or more to 50 GHz or less. However, the high frequency band may be divided into three or more fine bands and three or more capacitors may be used.

What is claimed is:

1. An electronic circuit comprising:
a first capacitor, which eliminates, when a frequency band is divided into a low frequency band and a high frequency band, the direct current component of the low frequency band; and
a plurality of second capacitors each disposed to each fine band when the high frequency band is further divided into fine bands to eliminate the direct current components of the fine bands,
wherein the first capacitor and the second capacitor are connected in parallel with each other.

2. An electronic circuit according to claim 1, wherein the electrostatic capacitance of the first capacitor is larger than the electrostatic capacitances of the plurality of second capacitors, and the electrostatic capacitances of the second capacitors are different from each other.

3. An electronic circuit according to claim 1 comprising:
a first conductive pattern extending in a strip shape; and
a second conductive pattern extending in a strip shape at a predetermined interval from the extreme end of the first conductive pattern,
wherein one electrodes of the first capacitor and the second capacitors are connected to the first conductive pattern, and the electronic circuit further comprises:
a conductive lead plate to which the other electrode of the first capacitor is connected as well as the other electrodes of the plurality of second capacitors are commonly connected and which is connected to the second conductive pattern.

4. An electronic circuit according to claim 3, wherein the connecting position of the lead plate at which the electrode of the capacitor, which eliminates the direct current component of the highest frequency fine band, of the plurality of capacitors is connected is located nearer to the second conductive pattern than the connecting position of the lead plate at which the electrode of the other capacitor is connected.

5. An electronic circuit according to claim 1 comprising:
a first conductive pattern extending in a strip shape; and
a second conductive pattern extending in a strip shape at a predetermined interval from the extreme end of the first conductive pattern,
wherein the first capacitor is disposed such that the electrode on one end side thereof is connected to the first conductive pattern and the electrode on the other end side thereof is disposed in an attitude in which the electrode is raised from the extreme end of the first conductive pattern, and the electronic circuit further comprises:
a lead plate which connects the electrode on the other end side of the first capacitor to the second conductive pattern,
wherein any of the plurality of second capacitors is sandwiched between the lead plate and the first conductive pattern in a direction where the pairs of electrodes of the second capacitors face.

6. A method of manufacturing an electronic circuit comprising:
a preparation step of preparing a low frequency capacitor, which eliminates the direct current component of a low frequency band, when a frequency band is divided into the low frequency band and a high frequency band, a first chip capacitor, which eliminates the direct current component of a lower frequency fine band, and a second chip capacitor which eliminates the direct current component of a higher frequency fine band, when the high frequency band is further divided into the lower frequency fine band and the higher frequency fine band;
a V-shape bending step of pressing the extreme end of a conductive lead plate extending horizontally against a V-shaped groove while keeping the rear end thereof horizontally to thereby form the side surface of the extreme end in a V-shape having a V-shaped apex so that there is formed a space, which is sandwiched between an extreme end side inclining portion that inclines from the extreme end to the V-shaped apex and a horizontal side inclining portion that inclines from the horizontal portion of the lead plate to the V-shaped apex;
a lead integration step of obtaining a lead integration member in which one electrode of the first chip capacitor is connected to the surface of the extreme end side inclining portion on the space side thereof as well as one electrode of the second chip capacitor is connected to the surface of the horizontal side including portion on the space side thereof, and a conductor is interposed between the other electrode of the first chip capacitor and the other electrode of the second chip capacitor;
a bridge step of disposing the lead integration member with the V-shaped apex facing upward so that the conductor is located on a first conductive pattern of a substrate having the first conductive pattern and a second conductive pattern disposed on the front surface thereof, the first conductive pattern extending in a strip shape, and the second conductive pattern extending in a strip shape at a predetermined interval from the extreme end of the first conductive pattern as well as the rear end of the lead plate is positioned on the second conductive pattern, and connecting the conductor to the first conductive pattern as well as connecting the rear end of the lead plate to the second conductive pattern; and
a low frequency capacitor connection step of disposing the low frequency capacitor so that the pair of electrodes thereof are disposed toward the first conductive pattern along the inclination of the extreme end side inclining portion, and connecting one electrode of the low frequency capacitor to the surface of the extreme end side inclining portion opposite to the surface thereof on the space side as well as connecting the other electrode of the low frequency capacitor to the first conductive pattern.

7. A method of manufacturing an electronic circuit according to claim 6, wherein the preparation step comprises preparing a chip capacitor having an electrostatic capacitance smaller than that of the first chip capacitor as the second chip capacitor as well as preparing a capacitor having an electrostatic capacitance larger than that of the first chip capacitor as the low frequency capacitor.

8. A method of manufacturing an electronic circuit according to claim 6, wherein the bridge step comprises disposing the lead integration member so that the conductor is in contact with the first conductive pattern as well as the rear end of the lead plate is in contact with the second conductive pattern, and securing the rear end of the lead plate to the second conductive pattern after the conductor is secured to the first conductive pattern.
